(19) United States
(12) Patent Application Publication
(10) Pub. No.: US 2018/0197861 A1
(43) Pub. Date: Jul. 12, 2018

(54) SEMICONDUCTOR DEVICES INCLUDING VARIED DEPTH RECESSES FOR CONTACTS

(71) Applicant: Samsung Electronics Co., Ltd, Suwon-si (KR)

(72) Inventors: Sang Jine Park, Yongin-si (KR); KI HYUNG KO, Yongin-si (KR); KEE SANG KWON, Hwaseong-si (KR); JAE JIK BAEK, Seongnam-si (KR); BO UN YOON, Seoul (KR); YONG SUN KO, Suwon-si (KR)

(21) Appl. No.: 15/916,513

(22) Filed: Mar. 9, 2018

Related U.S. Application Data
(63) Continuation of application No. 15/150,917, filed on May 10, 2016.

(30) Foreign Application Priority Data
May 27, 2015 (KR) 10-2015-0073726

(51) Int. Cl. H01L 27/092; H01L 29/78; H01L 21/02; H01L 29/66; H01L 21/3065; H01L 21/308; H01L 21/768; H01L 21/8234; H01L 21/8238; H01L 29/417; H01L 29/08; H01L 23/485; H01L 27/088; H01L 29/165

(52) U.S. Cl. CPC H01L 27/0924; H01L 29/665; H01L 21/02532; H01L 29/66545; H01L 29/6656; H01L 21/02636; H01L 21/3065; H01L 21/3081; H01L 21/76897; H01L 21/823437; H01L 21/823814; H01L 29/41791; H01L 29/41783; H01L 29/0847; H01L 23/485; H01L 21/823828; H01L 21/823821; H01L 21/76831; H01L 27/0886; H01L 21/76805; H01L 29/165; H01L 21/823418; H01L 21/823431; H01L 29/7848

(57) ABSTRACT

A first conductivity type finFET device can include first embedded sources/drains of a first material that have a first etch rate. The first embedded sources/drains can each include an upper surface having a recessed portion and an outer raised portion relative to the recessed portion. A second conductivity type finFET device can include second embedded sources/drains of a second material that have a second etch rate than is greater that the first etch rate. The second embedded sources/drains can each include an upper surface that is at a different level than the outer raised portions of the first conductivity type finFET device.

### CROSS-REFERENCE TO RELATED APPLICATION

This application is a continuation of U.S. patent application Ser. No. 15/150,917, filed May 10, 2016, which itself claims priority under 35 U.S.C. § 119 to Korean Patent Application No. 10-2015-0073726 filed on May 27, 2015, with the Korean Intellectual Property Office, the disclosures of both of which are hereby incorporated by reference in their entireties.

### FIELD

The present inventive concept relates to semiconductor devices and methods of manufacturing semiconductor devices.

### BACKGROUND

Semiconductor devices including three-dimensional FinFETs are being developed to overcome limitations in device characteristics (e.g. a short channel effect) due to the further miniaturization of the semiconductor devices. In order to improve the performance of semiconductor devices, methods of increasing charge carrier mobility and decreasing source/drain resistance are being studied.

### SUMMARY

Embodiments according to the inventive concept can provide semiconductor devices including varied depth recesses for contacts and methods of manufacturing the same. Pursuant to these embodiments, a first conductivity type finFET device can include first embedded sources/drains of a first material that have a first etch rate. The first embedded sources/drains can each include an upper surface having a recessed portion and an outer raised portion relative to the recessed portion. A second conductivity type finFET device can include second embedded sources/drains of a second material that have a second etch rate than is greater that the first etch rate. The second embedded sources/drains can each include an upper surface that is at a lower level than the raised portion of the first conductivity type finFET device.

In some embodiments according to the inventive concept, a semiconductor device, can include at least one active fin protruding from a substrate and a gate structure intersecting the at least one active fin. An embedded source/drain can be disposed on the active fin and include an upper surface having a recessed portion thereof that extends parallel to a direction in which the gate structure extends. A contact plug can partially cover the recessed portion, where the upper surface of the embedded source/drain can further include a raised portion relative to the recessed portion, where the raised portion can be located between the recessed portion and the gate structure.

In some embodiments according to the inventive concept, a method of manufacturing a semiconductor device, can include providing a substrate including first active fins, first sacrificial gates, and first sidewall spacers disposed in a first region, and second active fins, second sacrificial gates, and second sidewall spacers disposed in a second region. Second embedded sources/drains can be formed at both sides of the second sacrificial gates and first embedded sources/drains can be formed at both sides of the first sacrificial gates. A blocking insulating layer can be formed to cover the second embedded sources/drains and expose the first embedded sources/drains. The first embedded sources/drains can be etched using the first sidewall spacers as an etch mask to provide recessed portions of the first embedded sources/drains exposed by the first sidewall spacers. An etch-stop layer can be formed to cover the first sacrificial gates, the second sacrificial gates, the first embedded sources/drains, and the second embedded sources/drains. An interlayer insulating layer can be formed on the etch-stop layer and the interlayer insulating layer over the first and second embedded sources/drains can be simultaneously etched to provide first and second contact holes on the first and second embedded sources/drains, respectively.

In some embodiments according to the inventive concept, a method of manufacturing a semiconductor device can include providing first sacrificial gates and first sidewall spacers disposed in a first region of a substrate, and second sacrificial gates and second sidewall spacers disposed in a second region of the substrate and forming second embedded sources/drains comprising a second material at both sides of the second sacrificial gates. First embedded sources/drains can be formed to include a first material that is different from the second material, at both sides of the first sacrificial gates. A blocking insulating layer can be formed to cover the second embedded sources/drains and to expose the first embedded sources/drains. The first embedded sources/drains can be partially etched to provide recessed portions. An etch-stop layer can be formed on the first sacrificial gates, the second sacrificial gates, the first embedded sources/drains, and the second embedded sources/drains. A first interlayer insulating layer can be formed to expose upper surfaces of the first and second sacrificial gates on the etch-stop layer. The first and second sacrificial gates can be replaced with first and second gate structures, respectively. A second interlayer insulating layer can be formed to cover the first gate structures, the second gate structures, and the first interlayer insulating layer and the first and second interlayer insulating layers can be simultaneously etched to provide first contact holes that partially expose the first embedded sources/drains and to provide second contact holes that partially expose the second embedded sources/drains.

### BRIEF DESCRIPTION OF DRAWINGS

FIG. 1 is a plan view illustrating a semiconductor device according to an example embodiment of the present inventive concept;

FIGS. 2A and 2B are perspective views illustrating a semiconductor device according to an example embodiment of the present inventive concept;

FIGS. 3A to 9B are views illustrating a method of manufacturing a semiconductor device according to an example embodiment of the present inventive concept;

FIGS. 10 and 11 are views illustrating a method of manufacturing a semiconductor device according to an example embodiment of the present inventive concept;

FIGS. 12A to 13B are views illustrating a method of manufacturing a semiconductor device according to an example embodiment of the present inventive concept;

FIGS. 14A and 14B are perspective views illustrating a semiconductor device according to an example embodiment of the present inventive concept;

FIGS. 15A to 17B are views illustrating a method of manufacturing a semiconductor device according to an example embodiment of the present inventive concept;

FIGS. 18A and 18B are perspective views illustrating a semiconductor device according to an example embodiment of the present inventive concept;

FIGS. 19A and 19B are perspective views illustrating a semiconductor device according to an example embodiment of the present inventive concept;

FIG. 20 is a circuit diagram of a NAND gate cell including a semiconductor device according to an example embodiment of the present inventive concept;

FIG. 21 is a circuit diagram of an SRAM cell including a semiconductor device according to an example embodiment of the present inventive concept;

FIG. 22 is a block diagram illustrating a storage apparatus including a semiconductor device according to an example embodiment of the present inventive concept;

FIG. 23 is a block diagram illustrating an electronic apparatus including a semiconductor device according to an example embodiment of the present inventive concept; and

FIG. 24 is a block diagram illustrating a system including a semiconductor device according to an example embodiment of the present inventive concept.

### DETAILED DESCRIPTION

Example embodiments of the present inventive concept will now be described in detail with reference to the accompanying drawings.

The inventive concepts are described hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

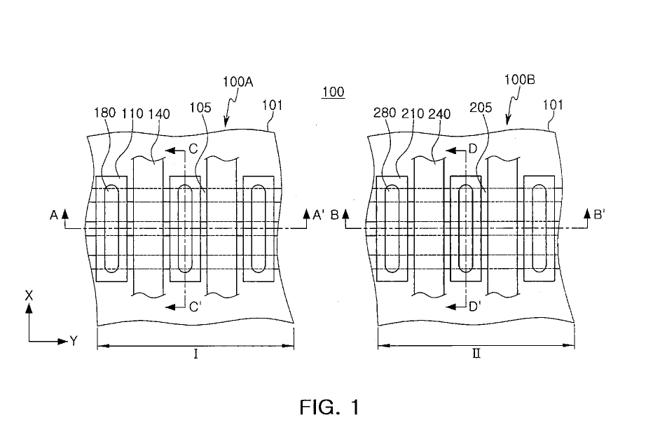

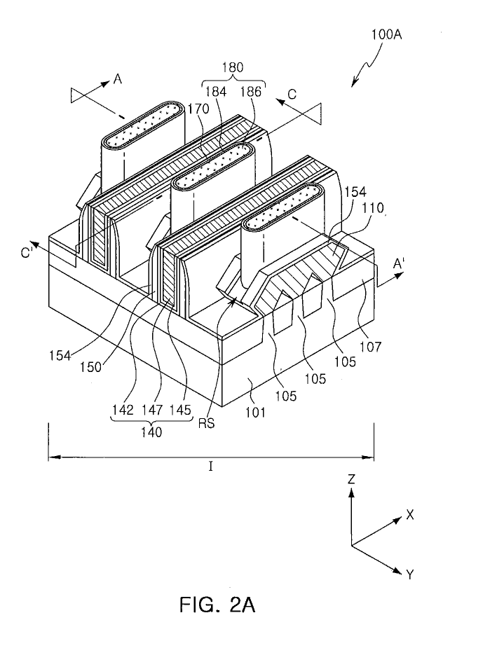

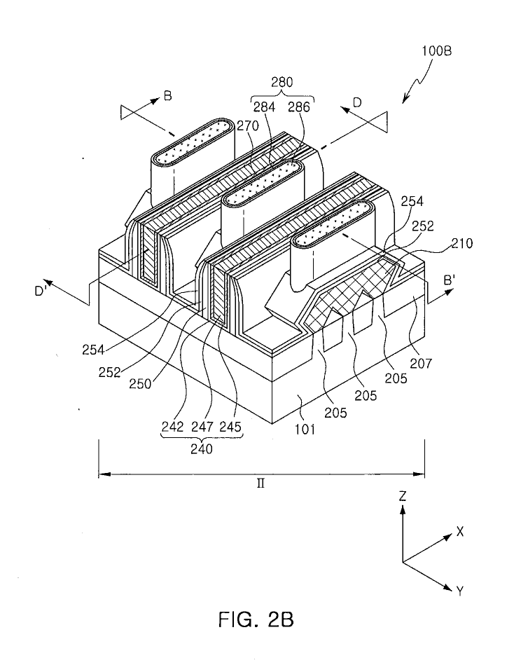

FIG. 1 is a plan view illustrating a semiconductor device according to an example embodiment of the present inventive concept. FIGS. 2A and 2B are perspective views illustrating a semiconductor device according to an example embodiment of the present inventive concept. For convenience of description, some components are omitted in FIGS. 1, 2A, and 2B. For example, only the positional relationship between main structures is illustrated in FIG. 1, and interlayer insulating layers are omitted in FIGS. 2A and 2B.

Referring to FIGS. 1, 2A, and 2B, a semiconductor device 100 may include a substrate 101 having a first region I and a second region II, first transistors 100A disposed in the first region I, and second transistors 100B disposed in the second region II.

The first transistors 100A may include first active fins 105, first gate structures 140, first sidewall spacers 150, first embedded sources/drains 110, and first contact plugs 180. The second transistors 100B may include second active fins 205, second gate structures 240, second sidewall spacers 250, second embedded sources/drains 210, a blocking insulating layer 252, and second contact plugs 280. The semiconductor device 100 may further include isolation layers 107 and 207, etch-stop layers 154 and 254, and contact spacers 170 and 270.

The first region I may be a region in which N-type FinFETs are formed, and the second region II may be a region in which P-type FinFETs are formed. That is, the first transistors 100A may be the N-type FinFETs, and the second transistors 100B may be the P-type FinFETs.

The substrate 101 may include an upper surface extending in an X-direction and a Y-direction. The substrate 101 may include a semiconductor material, such as a IV-group semiconductor, a III-V group compound semiconductor, or a II-VI compound semiconductor. For example, the substrate 101 may be a semiconductor substrate including silicon, germanium, or silicon-germanium, a silicon-on-insulator (SOI) substrate, or a germanium-on-insulator (GeOI) substrate.

The first and second active fins 105 and 205 may be disposed to extend in a first direction, such as the Y-direction on substrate 101. The first and second active fins 105 and 205 may have a structure of fins protruding from the substrate 101. The first and second active fins 105 and 205 may be formed by etching the substrate 101. In some example embodiments, the first and second active fins 105 and 205 may include an epitaxial layer grown from the substrate 101. For example, the first active fins 105 may be formed of silicon including P-type impurities, and the second active fins 205 may be formed of silicon including N-type impurities. The first active fins 105 and the second active fins 205 are illustrated as extending in the same direction, but are not limited thereto. The first active fins 105 and the second active fins 205 may extend in different directions.

The isolation layers 107 and 207 may be disposed between the first and second active fins 105 and 205. The isolation layers 107 and 207 may have a height to expose upper portions of the first and second active fins 105 and 205. The isolation layers 107 and 207 may be formed by a shallow trench isolation (STI) process, for example. The isolation layers 107 and 207 may be formed of an insulating material. The isolation layers 107 and 207 may include, for example, silicon oxide, silicon nitride, a low-k material, or a combination thereof. The low-k material may include boro-phospho-silicate glass (BPSG), tonen silazene (TOSZ), undoped silicate glass (USG), spin on glass (SOG), flowable oxide (FOX), tetra-ethyl-ortho-silicate (TEOS), or a high density plasma-CVD (HDP-CVD) oxide.

The first and second gate structures 140 and 240 may be disposed to substantially perpendicularly intersect the first and second active fins 105 and 205, respectively, and extend in a second direction such as in the X-direction on the substrate 101. Channel areas of transistors may be formed in the first and second active fins 105 and 205 intersecting the first and second gate structures 140 and 240. The first gate structures 140 and the second gate structures 240 are illustrated as extending in the same direction, but are not limited thereto. The first gate structures 140 and the second gate structures 240 may extend in different directions.

Each of the first gate structures 140 may include a first gate insulating layer 142, a first lower gate electrode 145, and a first upper gate electrode 147. The first gate insulating layer 142 may be disposed between the first active fins 105 and the first lower gate electrode 145. The first gate insulating layer 142 may extend to a space between the first sidewall spacer 150 and the first lower gate electrode 145. The first lower gate electrode 145 and the first upper gate electrode 147 may be sequentially disposed on the first gate insulating layer 142. Each of the second gate structures 240 may include a second gate insulating layer 242, a second lower gate electrode 245, and a second upper gate electrode 247. The second gate insulating layer 242 may be disposed between the second active fins 205 and the second lower gate electrode 245. The second gate insulating layer 242 may extend to a space between the second sidewall spacer 250 and the second lower gate electrode 245. The second lower gate electrode 245 and the second upper gate electrode 247 may be sequentially disposed on the second gate insulating layer 242.

The first and second gate insulating layers 142 and 242 may include silicon oxide, silicon oxynitride, silicon nitride, or a high-k material. The high-k material may be a dielectric material having a higher dielectric constant than silicon oxide (SiO₂). The high-k material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). The first and second lower gate electrodes 145 and 245 may include, for example, at least one selected from the group consisting of titanium nitride (TiN), tantalum nitride (TaN), tungsten nitride (WN), titanium aluminum nitride (TiAlN), titanium aluminum (TiAl), tantalum carbide (TaC), and titanium carbide (TiC). The first and second upper gate electrodes 147 and 247 may include a metal material, such as aluminum (Al), tungsten (W), or molybdenum (Mo), or a semiconductor material such as doped polysilicon.

Each of the first and second sidewall spacers 150 and 250 may be disposed on both sidewalls of the first and second gate structures 140 and 240. The first sidewall spacers 150 may be disposed between the first embedded sources/drains 110 and the first gate structures 140. The second sidewall spacer 250 may be disposed between the second embedded sources/drains 210 and the second gate structure 240. The first and second sidewall spacers 150 and 250 may include silicon oxide, silicon nitride, silicon oxynitride, or a low-k material. The first and second sidewall spacers 150 and 250 may be formed of a multilayer. For example, the first and second sidewall spacers 150 and 250 may have a stacked structure of a silicon nitride layer and a low-k layer.

The first embedded sources/drains 110 may be disposed on the first active fins 105 at both sides of the first gate structures 140. More specifically, the first embedded sources/drains 110 may be formed on areas at which the first active fins 105 are recessed. The first embedded sources/drains 110 may be provided as source areas or drain areas of the first transistors 100A. The first embedded sources/drains 110 may be elevated sources/drains whose upper surfaces are disposed higher than lower surfaces of the first gate structures 140. Each of the first embedded sources/drains 110 may have a merged or a connected structure on the first active fins 105. The number of the first active fins 105 may not be limited to that illustrated in FIG. 2A. Each of the first embedded sources/drains 110 having the merged structure may include inclined upper surfaces disposed at both end portions thereof and a flat upper surface disposed between the inclined upper surfaces. However, the shape of the first embedded sources/drains 110 is not limited to that illustrated in FIG. 2A. In some example embodiments, each of the first embedded sources/drains 110 having the merged structure may include an upper surface that is partially concave between the first active fins 105.

Each of the first embedded sources/drains 110 may include a recessed portion RS parallel to the first gate structure 140. That is, each of the first embedded sources/drains 110 may include the recessed portion RS extending parallel to the direction in which the first gate structure 140 extends. The recessed portion RS may be disposed throughout the upper surface of the first embedded source/drain 110 in the direction in which the first gate structure 140 extends. The recessed portion RS may be formed to be spaced apart from the first sidewall spacer 150 by a particular distance. The recessed portion RS may have a shape to which the shape of the upper surface of the first embedded source/drain 110 is transferred. Each of the first embedded sources/drains 110 may include a raised portion relative to a recessed portion RS and the raised portion located between the recessed portion and the first gate structure 140.

The first embedded sources/drains 110 may be epitaxial layers grown by a selective epitaxial growth process. The first embedded sources/drains 110 may include, for example, silicon or silicon carbide (SiC) in which N-type impurities are doped with a high concentration.

The second embedded sources/drains 210 may be disposed at both sides of the second gate structures 240 on areas at which the second active fins 205 are recessed. The second embedded sources/drains 210 may be provided as source areas or drain areas of the second transistors 100B. Upper surfaces of the second embedded sources/drains 210 may be formed to have substantially the same height as lower surfaces of the second gate structures 240. In some example embodiments, the second embedded sources/drains 210 may be elevated sources/drains whose upper surfaces are disposed higher than the lower surfaces of the second gate structures 240. Upper surfaces of the second embedded sources/drains 210 may be at a different level from the outer raised portions of the first embedded sources/drains 110. For example, upper surfaces of the second embedded sources/drains 210 may be at a lower level from the outer raised portions of the first embedded sources/drains 110. Each of the second embedded sources/drains 210 may have a connected or merged structure on the second active fins 205. The number of the connected second active fins 205 is not limited to that illustrated in FIG. 2B. Each of the second embedded sources/drains 210 having the merged structure may have inclined upper surfaces disposed at both end portions thereof and a flat surface disposed between the inclined upper surfaces. However, the shape of the second embedded sources/drains 210 is not limited to that illustrated in FIG. 2B. In some example embodiments, each of the second embedded sources/drains 210 having the merged structure may include an upper surface that is partially concave between the second active fins 205.

The second embedded sources/drains 210 may be epitaxial layers grown by a selective epitaxial growth process. The second embedded sources/drains 210 may include, for example, silicon-germanium (SiGe) in which P-type impurities are doped with a high concentration. For example, when the second embedded sources/drains 210 include silicon-germanium (SiGe), compressive stress may be applied to channel areas, portions of the second active fins 205 formed of silicon (Si). Accordingly, hole mobility in the channel areas may be improved.

The blocking insulating layer 252 may be formed to have a substantially uniform thickness on the second sidewall spacers 250, isolation layers 207, and second embedded sources/drains 210 disposed on the substrate 101. The etch-stop layer 254 may be disposed to have a substantially uniform thickness on the blocking insulating layer 252. The blocking insulating layer 252 may be formed of silicon nitride, silicon oxynitride, or a combination thereof.

The etch-stop layers 154 and 254 may have substantially uniform thicknesses on the first and second sidewall spacers 150 and 250, the isolation layers 107 and 207, the first and second embedded sources/drains 110 and 210, and the recessed portions RS formed in the first embedded sources/drains 110, disposed on the substrate 101. The etch-stop layers 154 and 254 may be formed of silicon nitride, silicon oxynitride, or a combination thereof.

The first and second contact plugs 180 and 280 may be respectively disposed on the first and second embedded sources/drains 110 and 210 and may have elongated horizontal cross-sections. In other words, the first and second contact plugs 180 and 280 may have a shape elongated in directions in which the first and second gate structures 140 and 240 extend (such as in the X-direction). In addition, the first and second contact plugs 180 and 280 may have rectangular or oval shapes when viewed in a plan view.

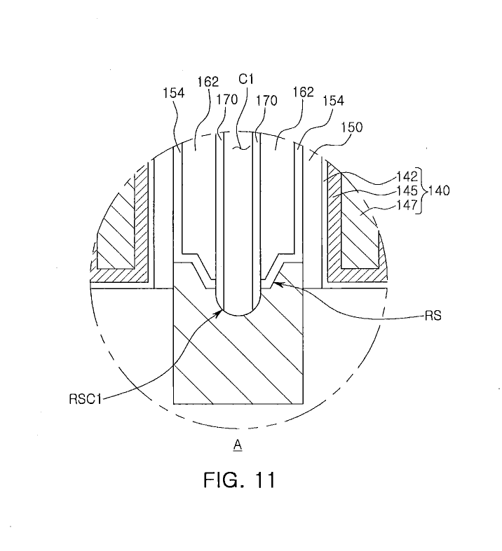

The first contact plugs 180 may pass through the etch-stop layer 154 to be connected to the first embedded sources/drains 110. The first contact plugs 180 may be disposed to cover portions of the recessed portions RS of the first embedded sources/drains 110. The etch-stop layer 154 may remain on the recessed portions RS on which the first contact plugs 180 are not formed. Widths (for example, sizes in the Y-direction) of the first contact plugs 180 may not be the same as widths of the recessed portions RS. When the widths of the first contact plugs 180 are narrower than the widths of the recessed portions RS, the etch-stop layer 154 may remain between the first contact plugs 180 and side surfaces of the recessed portions RS (refer to FIG. 11). Lengths (for example, sizes in the X-direction) of the first contact plugs 180 may not be the same as lengths of the recessed portions RS. When the lengths of the first contact plugs 180 are shorter than the lengths of the recessed portion RS, the etch-stop layer 154 may remain at both sides of the first contact plugs 180 on the recessed portions RS.

The second contact plugs 280 may pass through the etch-stop layer 254 and the blocking insulating layer 252 to connect to the second embedded sources/drains 210.

The first and second contact plugs 180 and 280 may include first conductive layers 184 and 284 and second conductive layers 186 and 286. The first conductive layers 184 and 284 may be conformally formed on lower surfaces and sidewalls of the first and second contact plugs 180 and 280. The first conductive layers 184 and 284 may include, for example, at least one of metal nitrides such as titanium nitride (TiN), tantalum nitride (TaN), and tungsten nitride (WN). The second conductive layers 186 and 286 may include a conductive material such as aluminum (Al), copper (Cu), tungsten (W), or molybdenum (Mo).

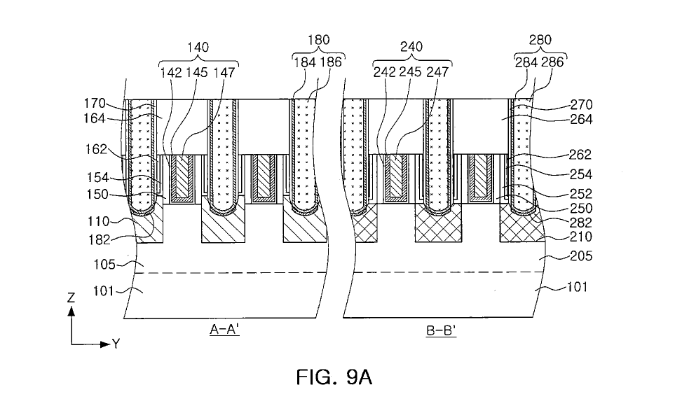

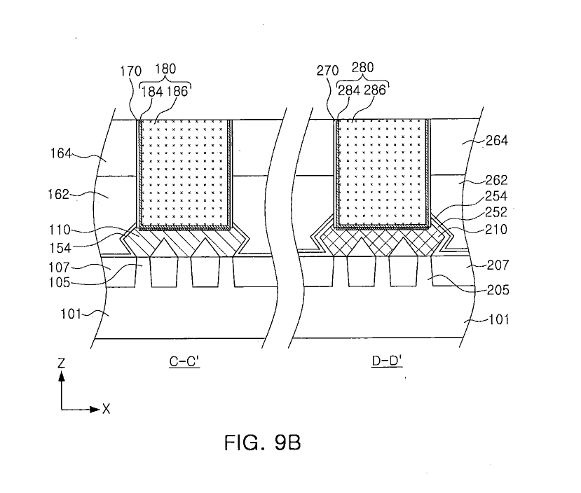

Silicide layers 182 and 282 may be disposed between the first contact plugs 180 and the first embedded sources/drains 110, and between the second contact plugs 280 and the second embedded sources/drains 210 (refer to FIG. 9A). The silicide layers 182 and 282 may be metal silicide layers formed by a reaction of portions of the first conductive layers 184 and 284 with the first and second embedded sources/drains 110 and 210. Alternatively, the silicide layers 182 and 282 may be metal silicide layers formed by a reaction of another metal material with the first and second embedded sources/drains 110 and 210. In some example embodiments, the silicide layers 182 and 282 may be omitted. The silicide layers 182 and 282 may be, for example, titanium silicide (TiSi). The first conductive layer 184 may function as a diffusion barrier layer against the second conductive layer 186. The contact spacers 170 and 270 surrounding the first and second contact plugs 180 and 280 may include silicon oxide, silicon oxynitride, silicon nitride, or a low-k material.

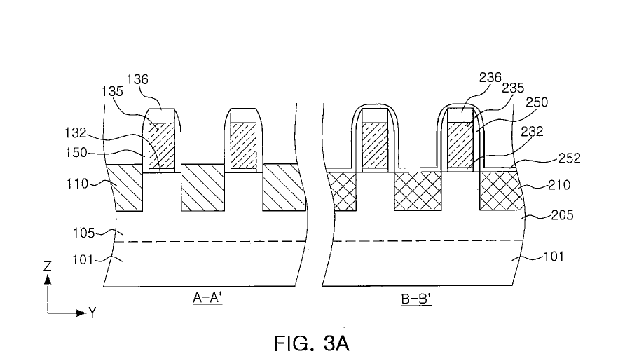

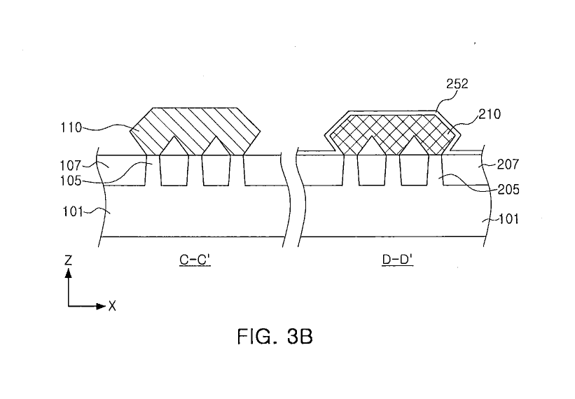

FIGS. 3A to 9B are views illustrating a method of manufacturing a semiconductor device according to an example embodiment of the present inventive concept.

FIGS. 3A to 9A are cross-sectional views taken along lines A-A′ and B-B′ of FIG. 1. FIGS. 3B to 9B are cross-sectional views taken along lines C-C′ and D-D′ of FIG. 1. In FIGS. 3A to 9B, the cross-sectional views marked by A-A′ and C-C′ illustrate the first region I in FIG. 1, and cross-sectional views marked by B-B′ and D-D′ illustrate the second region II in FIG. 1.

Referring to FIGS. 3A and 3B, a substrate 101 including a first region and a second region may be provided. The first region of the substrate 101 may include first active fins 105, first sacrificial gates 135 intersecting the first active fins 105, first sacrificial gate insulating layers 132 disposed below the first sacrificial gates 135, first gate mask patterns 136 disposed on the first sacrificial gates 135, first sidewall spacers 150 disposed on sidewalls of the first sacrificial gates 135, first embedded sources/drains 110 disposed at both sides of the first sacrificial gates 135 on the first active fins 105, and an isolation layer 107 disposed between the first active fins 105. In addition, the second region of the substrate 101 may include second active fins 205, second sacrificial gates 235 intersecting the second active fins 205, second sacrificial gate insulating layers 232 disposed below the second sacrificial gates 235, second gate mask patterns 236 disposed on the second sacrificial gates 235, second sidewall spacers 250 disposed on sidewalls of the second sacrificial gates 235, second embedded sources/drains 210 disposed at both sides of the second sacrificial gates 235 on the second active fins 205, an isolation layer 207 disposed between the second active fins 205, and a blocking insulating layer 252 covering the entire structures of the second region.

The first active fins 105 may be formed in the first region by forming mask patterns on the substrate 101 and etching the substrate 101 by using the mask patterns as etch masks, and the second active fins 205 may be formed in the second region. Trenches may be formed between the first and second active fins 105 and 205 by the etching process. The isolation layers 107 and 207 may be formed by filling lower portions of the trenches with an insulating material. As a result, upper portions of the first and second active fins 105 and 205 may protrude above the isolation layers 107 and 207.

After forming a gate insulating layer and a gate electrode layer covering the first and second active fins 105 and 205, the first gate mask patterns 136 may be formed in the first region, and the second gate mask patterns 236 may be formed in the second region. The gate insulating layer and the gate electrode layer may be anisotropically etched using the first and second gate masks 136 and 236 as etch masks. Thereby, the first sacrificial gate insulating layers 132 and the first sacrificial gates 135 extending to intersect the first active fins 105 may be formed in the first region, and the second sacrificial gate insulating layers 232 and the second sacrificial gates 235 extending to intersect the second active fins 205 may be formed in the second region. For example, the first and second sacrificial gate insulating layers 132 and 232 may include silicon oxide, and the first and second sacrificial gates 135 and 235 may include polysilicon.

The first sidewall spacers 150 may be formed on the sidewalls of the first sacrificial gates 135, and the second sidewall spacers 250 may be formed on the sidewalls of the second sacrificial gates 235, by forming an insulating layer covering the first and second sacrificial gates 135 and 235 and the first and second active fins 105 and 205 and performing an etchback process. The first and second sidewall spacers 150 and 250 may include silicon oxide, silicon nitride, or silicon oxynitride. The first and second sidewall spacers 150 and 250 are illustrated as being formed in a single layer, but are not limited thereto. The first and second sidewall spacers 150 and 250 may be formed in multilayers.

Fin recesses may be formed at both sides of the second sidewall spacers 250 by selectively etching the second active fins 205 after forming a protection layer covering the first region of the substrate 101. The second embedded sources/drains 210 filling the fin recesses may be formed using a selective epitaxial growth (SEG) process. Upper surfaces of the second embedded sources/drains 210 are illustrated as being formed substantially at the same level as upper surfaces of the second active fins 205, but are not limited thereto. In some example embodiments, the upper surfaces of the second embedded sources/drains 210 may be formed higher than the upper surfaces of the second active fins 205. The second embedded sources/drains 210 may be, for example, a silicon germanium (SiGe) layer. Although the second embedded sources/drains 210 are illustrated as a single layer, the second embedded sources/drains 210 may include two or more silicon germanium layers having different germanium concentrations. During the process of growing the second embedded sources/drains 210, P-type impurities such as boron (B) may be in-situ doped. The second embedded sources/drains 210 may be formed to have a merged structure while growing on the second active fins 205.

The protection layer covering the first region of the substrate 101 may be removed, and the blocking insulating layer 252 covering the second region of the substrate 101 may be formed. The blocking insulating layer 252 may be conformally formed to have a substantially uniform thickness on surfaces of the second embedded sources/drains 210, the second gate mask patterns 236, and the second sidewall spacers 250. The blocking insulating layer 252 may be formed of, for example, silicon nitride.

Fin recesses may be formed by selectively etching portions of the first active fins 105 at both sides of the first sidewall spacers 150 in the first region. The first embedded sources/drains 110 filling the fin recesses may be formed using an SEG process. Upper surfaces of the first embedded sources/drains 110 are illustrated as being formed higher than upper surfaces of the first active fins 105, but are not limited thereto. The first embedded sources/drains 110 may be formed of a different material from the second embedded sources/drains 210. The first embedded sources/drains 110 may be, for example, a silicon (Si) layer. During the process of growing the first embedded sources/drains 110, N-type impurities such as phosphors (P) may be in-situ doped. The first embedded sources/drains 110 may be formed to have a merged structure while growing on the first active fins 105.

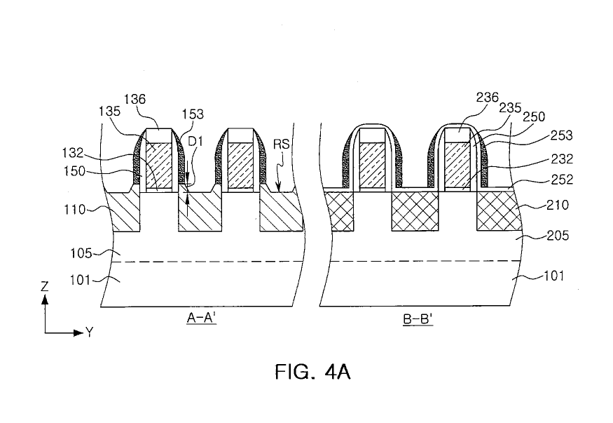

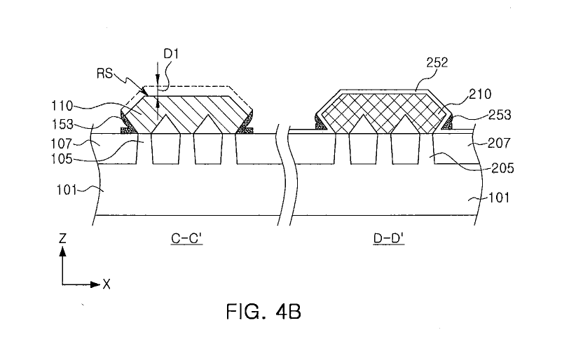

Referring to FIGS. 4A and 4B, recessed portions RS may be formed in the first embedded sources/drains 110 of the first region.

Third sidewall spacers 153 and 253 may be formed by forming an insulating layer having a given thickness and covering both of the first region and second region in the substrate 101 and performing an etchback process. The third sidewall spacers 153 formed in the first region may be disposed on one sides of the first sidewall spacers 150 to partially cover the upper surfaces of the first embedded sources/drains 110. The third sidewall spacers 153 and 253 may be formed of, for example, silicon oxide. The third sidewall spacers 153 and 253 may be formed by an atomic layer deposition (ALD) process.

The recessed portions RS spaced apart from the first sidewall spacers 150 at a given distance may be formed by selectively removing portions of the first embedded sources/drains 110 by using the third sidewall spacers 153 formed in the first region as etch masks. The distance between the recessed portions RS and the first sidewall spacers 150 may be determined by a thickness of the third sidewall spacers 153. That is, the recessed portions RS may be formed at locations spaced apart from the first sidewall spacers 150 by the thickness of the third sidewall spacers 153. The recessed portions RS may be formed to have a given depth D1 from the upper surfaces of the first embedded sources/drains 110. The recessed portion RS may have a shape to which a shape of the upper surfaces of the first embedded sources/drains 110 is transferred.

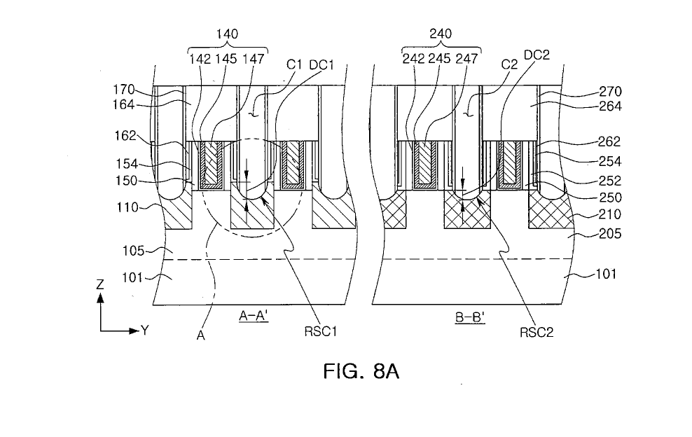

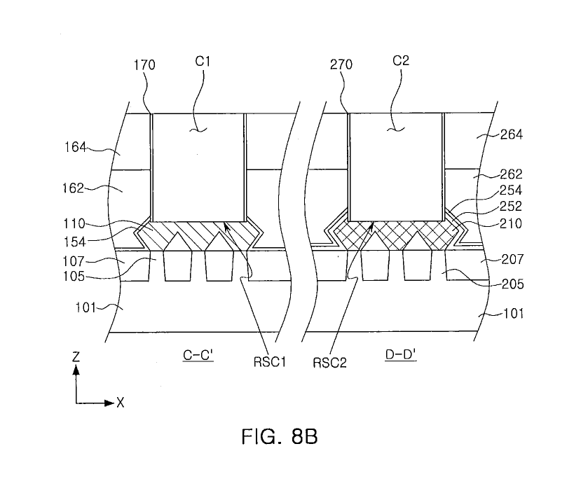

Accordingly, in some embodiments, when the first contact holes C1 and the second contact holes C2 are simultaneously formed to expose the first and second embedded sources/drains 110 and 210 by patterning interlayer insulating layers (refer to FIGS. 8A and 8B), the depth of contact recesses RSC1 of the first contact holes C1 may be controlled separately from the depth of the second contact holes C2 by forming the recessed portion RS previously. The term “depths of contact recesses” as used in this application may be understood as depths of lower surfaces of contact holes recessed from upper surfaces of embedded sources/drains.

As appreciated by the present inventors, during an etching process by which the contact holes C1 and C2 are simultaneously formed on the first and second embedded sources/drains 110 and 210, upper portions of the first and second embedded sources/drains 110 and 210 may be partially removed. Here, when the second embedded sources/drains 210 are silicon germanium layers and the first embedded sources/drains 110 are silicon layers, an etching rate of the first embedded sources/drains 110 may be less than that of the second embedded sources/drains 210. Thus, the depths of the contact recesses RSC1 formed on the first embedded sources/drains 110 may be shallower than depths of contact recesses RSC2 formed on the second embedded sources/drains 210. When a contact recess is shallow, a contact area of a contact plug formed therein may be small and contact resistance of the contact plug may increase.

Therefore, by forming the recessed portions RS in the first embedded sources/drains 110 first, and forming recesses in the process of etching the contact holes according to an example embodiment, the depth of the contact recesses RSC1 of the first contact holes C1 may be independently adjusted to a desired level. Further, the contact resistance of the contact plugs may be reduced. A depth of the recessed portion RS of the first embedded sources/drains 110 is selected to compensate for a difference between the etching rate of the first embedded sources/drains 110 and the etching rate of second embedded sources/drains 210.

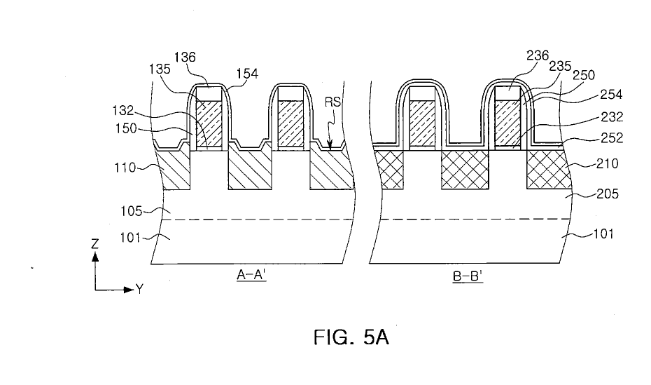

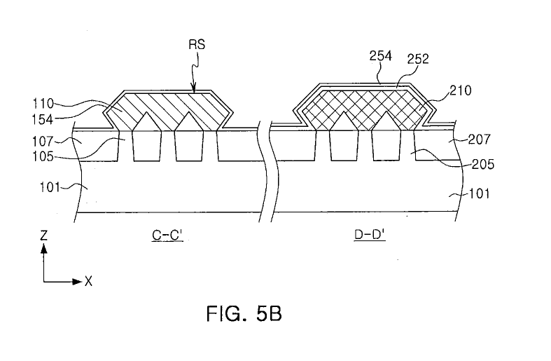

Referring to FIGS. 5A and 5B, the third sidewall spacers 153 and 253 may be removed by performing a pre-cleaning process and etch-stop layers 154 and 254 may be formed in the first region and the second region.

In the first region, the etch-stop layer 154 may be formed to have a given thickness on the first sidewall spacers 150, the recessed portions RS, and the first embedded sources/drains 110. In the second region, the etch-stop layer 254 may be formed to have a given thickness on the blocking insulating layer 252, The etch-stop layers 154 and 254 may be formed of silicon nitride. The etch-stop layers 154 and 254 may be formed by an ALD process.

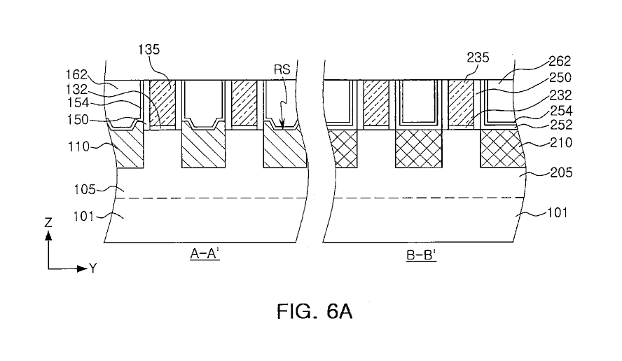

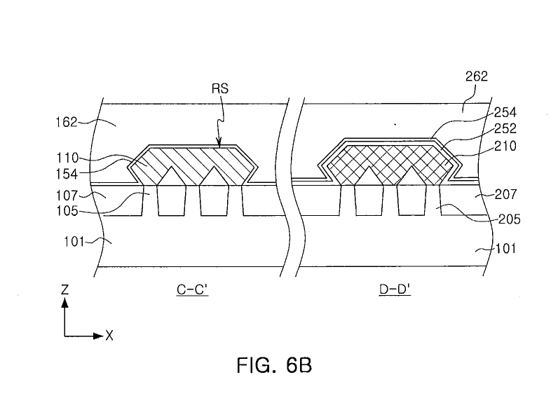

Referring to FIGS. 6A and 6B, first interlayer insulating layers 162 and 262 exposing upper surfaces of the first and second sacrificial gates 135 and 235 may be formed on the etch-stop layers 154 and 254.

The first interlayer insulating layers 162 and 262 may be formed by forming an insulating layer on the etch-stop layers 154 and 254 and performing a planarization process to expose the upper surfaces of the first and second sacrificial gates 135 and 235. Accordingly, the first and second gate masks 136 and 236 may be removed in this process. Alternatively, in some example embodiments, the first and second gate masks 136 and 236 may remain on the first and second sacrificial gates 135 and 235, and the remaining first and second gate masks 136 and 236 may be removed in a subsequent process.

The first interlayer insulating layers 162 and 262 may include boro-phospho-silicate glass (BPSG), tonen silazene (TOSZ), undoped silicate glass (USG), spin on glass (SOG), flowable oxide (FOX), tetra-ethyl-ortho-silicate (TEOS), or a high density plasma-CVD (HDP-CVD) oxide. The first interlayer insulating layers 162 and 262 may be formed by a chemical vapor deposition (CVD) process, a plasma enhanced-CVD (PE-CVD) process, a spin coating process, or an ALD process.

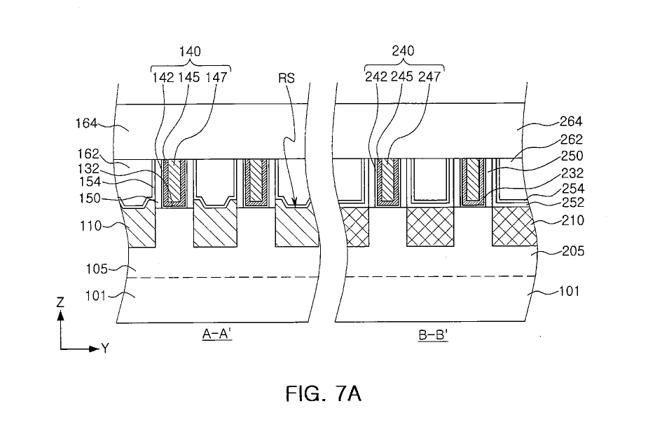

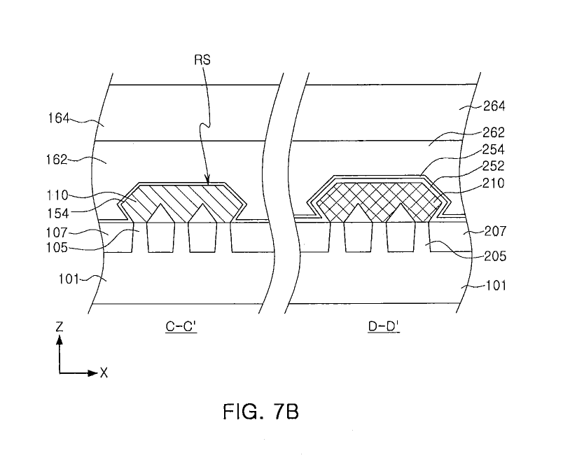

Referring to FIGS. 7A and 7B, first and second gate structures 140 and 240 may be formed, and then second interlayer insulating layers 164 and 264 may be formed on the first interlayer insulating layers 162 and 262 and the first and second gate structures 140 and 240.

The first and second sacrificial gate insulating layers 132 and 232, and the first and second sacrificial gates 135 and 235 may be removed. The first and second sacrificial gate insulating layers 132 and 232, and the first and second sacrificial gates 135 and 235 may be selectively removed with respect to the isolation layers 107 and 207 and first and second active fins 105 and 205 disposed thereunder, to form openings partially exposing the isolation layers 107 and 207 and the first and second active fins 105 and 205. The process of removing the first and second sacrificial gate insulating layers 132 and 232 and the first and second sacrificial gates 135 and 235 may include at least one of a dry etching process and a wet etching process.

The first gate structures 140 and the second gate structures 240 may be formed by sequentially forming first and second gate insulating layers 142 and 242, first and second lower gate electrodes 145 and 245, and first and second upper gate electrodes 147 and 247 in the openings, and performing a planarization process. In some example embodiments, the first lower gate electrodes 145 and the second lower gate electrodes 245 may include different materials. In this case, an additional deposition and etching process may be used.

The second interlayer insulating layers 164 and 264 may be formed by forming an insulating layer covering the first interlayer insulating layers 162 and 262 and the gate structures 140 and 240 and performing a planarization process. The second interlayer insulating layers 164 and 264 may include boro-phospho-silicate glass (BPSG), tonen silazene (TOSZ), undoped silicate glass (USG), spin on glass (SOG), flowable oxide (FOX), tetra-ethyl-ortho-silicate (TEOS), or a high density plasma-CVD (HDP-CVD) oxide. The second interlayer insulating layers 164 and 264 may be formed by a CVD process, a PE-CVD process, a spin coating process, or an ALD process.

Referring to FIGS. 8A and 8B, the first and second contact holes C1 and C2, partially exposing the first embedded sources/drains 110 and the second embedded sources/drains 210, may be formed. Contact spacers 170 and 270 may be formed on sidewalls of the first and second contact holes C1 and C2.

The first interlayer insulating layers 162 and 262 and the second interlayer insulating layers 164 and 264 may be etched using a mask pattern such as a photoresist pattern, to form preliminary contact holes partially exposing the etch-stop layers 154 and 254. Next, an insulating layer may be conformally formed on inner surfaces of the preliminary contact holes. The insulating layer may also be formed on the exposed etch-stop layers 154 and 254.

The first contact holes C1 partially exposing the first embedded sources/drains 110 may be formed by etching the insulating layer and the etch-stop layer 154 retained in lower portions of the preliminary contact holes in the first region using an additional etching process. Here, the contact spacers 170 may be formed on the sidewalls of the first contact holes C1. In addition, the second contact holes C2 partially exposing the second embedded sources/drains 210 may be formed by etching the insulating layer, the etch-stop layer 254, and the blocking insulating layer 252 retained in lower portions of the preliminary contact holes in the second region using the additional etching process. Here, the contact spacers 270 may be formed on the sidewalls of the second contact holes C2. The etching process for forming the first and second contact holes C1 and C2 may be simultaneously performed.

While the first contact holes C1 are formed, upper portions of the first embedded sources/drains 110 having the recessed portions RS may be partially etched to form the contact recesses RSC1. Since the first contact holes C1 are formed on the recessed portions RS of the first embedded sources/drains 110, the first embedded sources/drains 110 may be additionally etched from lower surfaces of the recessed portions RS to form the contact recesses RSC1 having a first depth DC1. While the second contact holes C2 are formed, upper surfaces of the second embedded sources/drains 210 may be partially etched to form the contact recesses RSC2 having a second depth DC2. For example, respective bottoms of the first and second contact holes C1 and C2 are about level with one another. That is, respective bottoms of the first and second contact plugs (180 and 280 in FIGS. 9A and 9B) are about level with one another.

Referring to FIGS. 9A and 9B, the first and second contact plugs 180 and 280 may be formed by filling the first and second contact holes C1 and C2 with a conductive material.

The first and second contact holes C1 and C2 may be filled by sequentially depositing first conductive layers 184 and 284 and second conductive layers 186 and 286. The first and second contact plugs 180 and 280 may be formed by performing a planarization process to expose upper surfaces of the second interlayer insulating layers 164 and 264. Silicide layers 182 and 282 formed between the first and second contact plugs 180 and 280 and the embedded sources/drains 110 and 210 may include a metal silicide formed by a reaction of the first conductive layers 184 and 284 with the embedded sources/drains 110 and 210 in this process or in a subsequent process. Alternatively, the silicide layers 182 and 282 may include a metal silicide formed by a reaction of another metal material with the embedded sources/drains.

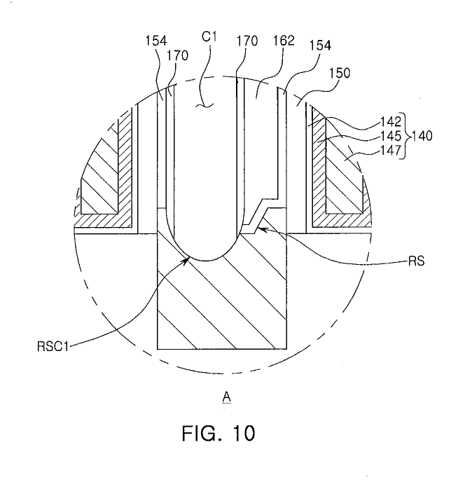

FIGS. 10 and 11 are views illustrating a method of manufacturing a semiconductor device according to an example embodiment of the present inventive concept. FIGS. 10 and 11 are enlarged views taken from the portion A of FIG. 8A. FIG. 10 illustrates a cross-sectional structure according to an alignment state of a first contact hole C1, and FIG. 11 illustrates a cross-sectional structure according to a size of the first contact hole C1.

Referring to FIG. 10, when the first contact hole C1 is not centered between the adjacent first gate structures 140 disposed at both sides thereof, but biased toward one or the other in a direction (for example, the Y-direction), an upper surface of a first embedded source/drain 110 may have a stepped etching profile at one side of the first contact hole C1 due to a recessed portion RS and a first contact recess RSC1. An etch-stop layer 154 formed in the recessed portion RS may remain between the first contact hole C1 and the recessed portion RS.

Referring to FIG. 11, when a width (for example, a size in the Y-direction) of the first contact hole C1 is less than that of the recessed portion RS, the recessed portion RS may remain at both sides of the first contact hole C1. An upper portion of the first embedded source/drain 110 may have a stepped etching profile at both sides of the first contact hole C1 due to the recessed portion RS and the first contact recess RSC1. The etch-stop layer 154 formed in the recessed portion RS may remain between the first contact hole C1 and the recessed portion RS.

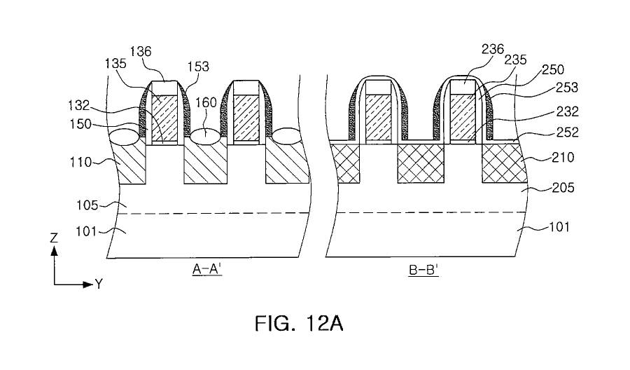

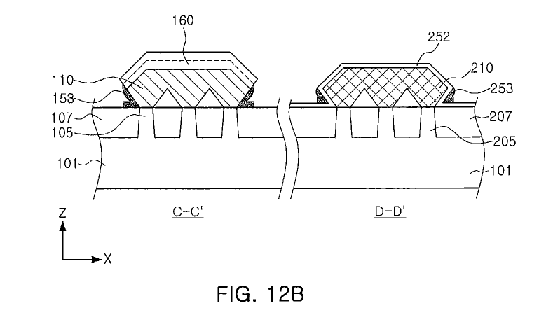

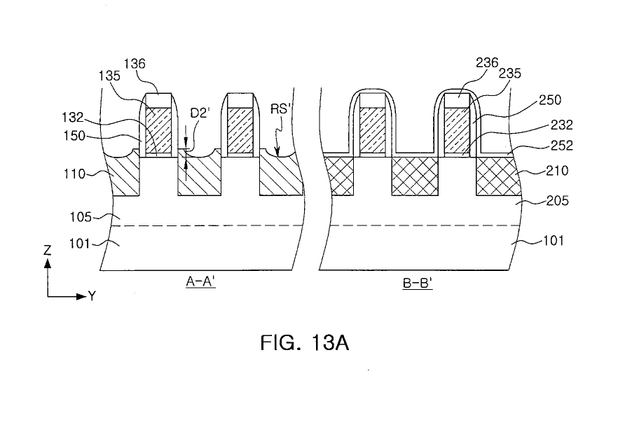

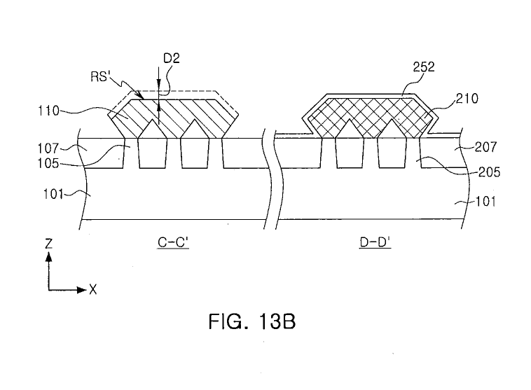

FIGS. 12A to 13B are views illustrating a method of manufacturing a semiconductor device according to an example embodiment of the present inventive concept.

Although the method of forming the recessed portions RS in the first embedded sources/drains 110 using a dry etching process is described with reference to FIGS. 4A and 4B, the recessed portions RS' may be formed in the first embedded sources/drains 110 by an oxidation process and a wet etching process. This will be described with reference to FIGS. 12A to 13B.

Referring to FIGS. 12A and 12B, a sacrificial oxide layer 160 may be formed on the first embedded sources/drains 110 in the first region.

After performing the processes described with reference to FIGS. 3A and 3B, an insulating layer having a given thickness and covering the first and second regions of the substrate 101 may be formed and an etchback process may be performed, to form third sidewall spacers 153 and 253. The third sidewall spacers 153 formed in the first region may be disposed on one sides of the first sidewall spacers 150 to partially cover upper surfaces of the first embedded sources/drains 110. Sacrificial oxide layers 160 may be formed by performing an oxidation process on the first embedded sources/drains 110 exposed between the third sidewall spacers 153 in the first region. The sacrificial oxide layers 160 may include bird's beaks formed under the third sidewall spacers 153. The oxidation process may be a thermal oxidation process or a radical oxidation process.

Referring to FIGS. 13A and 13B, recessed portions RS' spaced apart from the first sidewall spacers 150 at a given distance may be formed by selectively removing the third sidewall spacers 153 and 253 and the sacrificial oxide layers 160 using a wet etching process. The given distance may be determined depending on a thickness of the third sidewall spacers 153. The recessed portions RS' may be formed to have a given depth D2 from the upper surfaces of the first embedded sources/drains 110. The recessed portions RS' may have a shape to which a shape of the upper surfaces of the first embedded sources/drains 110 is transferred.

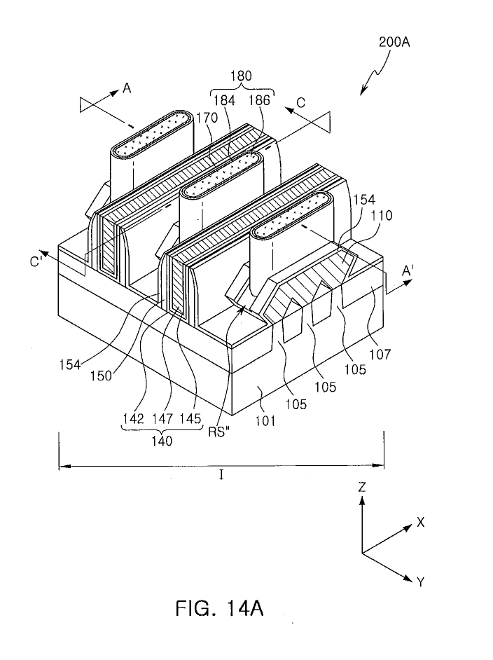

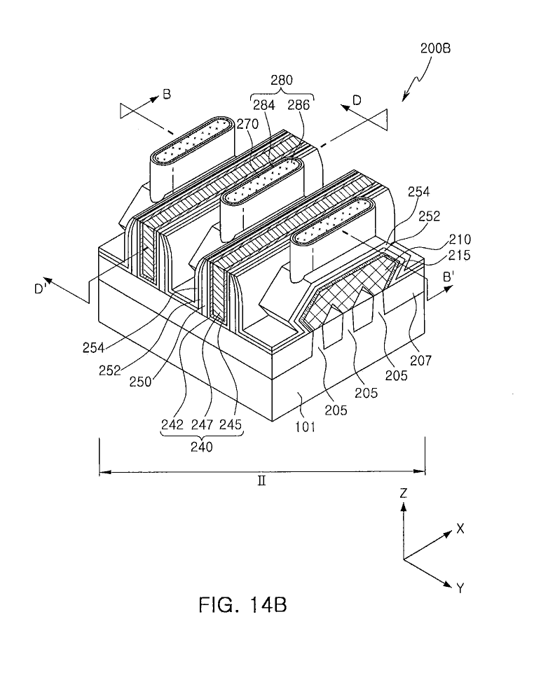

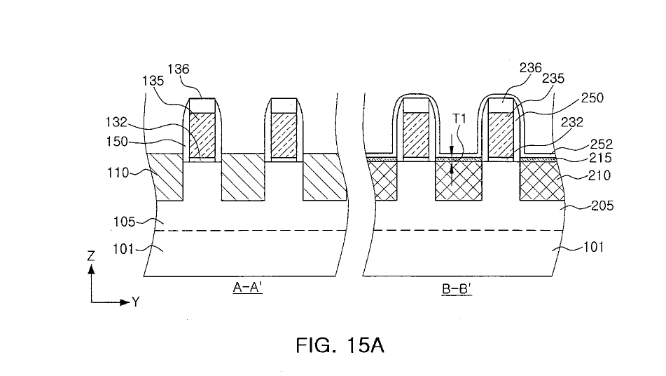

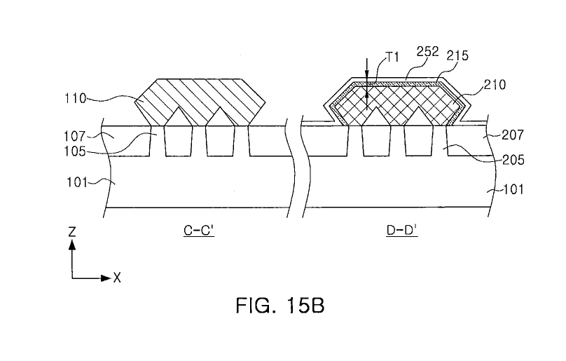

FIGS. 14A and 14B are perspective views illustrating a semiconductor device according to an example embodiment of the present inventive concept. FIGS. 15A to 17B are views illustrating a method of manufacturing a semiconductor device according to an example embodiment of the present inventive concept.

Referring to FIGS. 14A and 14B, although similar to those illustrated in FIGS. 2A and 2B, second transistors 200B may further include capping layers 215 formed on second embedded sources/drains 210. The capping layers 215 may have the same etching rate as the first embedded sources/drains 110. For example, when the first embedded sources/drains 110 are formed of silicon, the capping layers 215 may be formed of silicon.

Referring to FIGS. 15A and 15B, a substrate 101 including a first region and a second region may be provided. Although structures formed on the substrate 101 are similar to those illustrated in FIGS. 3A and 3B, capping layers 215 may be formed on the second embedded sources/drains 210 in the second region. The capping layers 215 may be successively formed using an SEG process after the second embedded sources/drains 210 are formed. The capping layers 215 may have a given thickness T1. The thickness T1 of the capping layers 215 may be appropriately determined in consideration of depths of contact recesses of second contact plugs 280 to be formed on the second embedded sources/drains 210. A blocking insulating layer 252 may be formed to cover the capping layers 215.

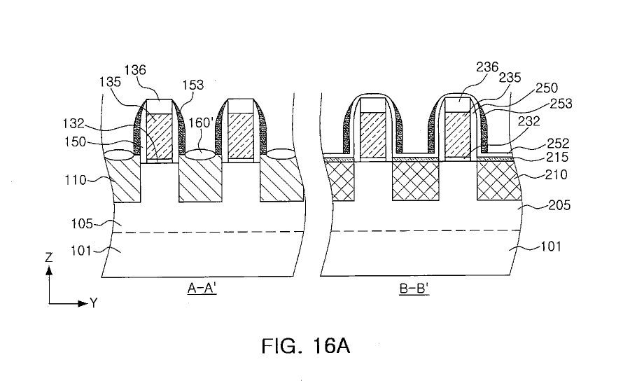

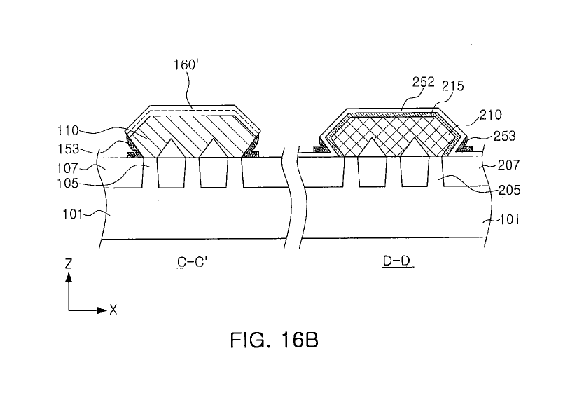

Referring to FIGS. 16A and 16B, sacrificial oxide layers 160′ may be formed on the first embedded sources/drains 110 in the first region.

Third sidewall spacers 153 and 253 may be formed by forming an insulating layer covering the entire first and second regions of the substrate 101 and performing an etchback process. The sacrificial oxide layers 160′ may be formed by performing an oxidation process on the first embedded sources/drains 110 exposed between the third sidewall spacers 153 in the first region. The sacrificial oxide layers 160′ may include bird's beaks formed under the third sidewall spacers 153. The sacrificial oxide layers 160′ may have smaller thicknesses than the sacrificial oxide layers 160 described with reference to FIGS. 12A and 12B. According to the example embodiment of the present inventive concept, the oxidation process time may be reduced compared to the example embodiment described with reference to FIGS. 12A to 13B, and a thermal budget caused by the oxidation process may be reduced. The oxidation process may be a thermal oxidation process or a radical oxidation process.

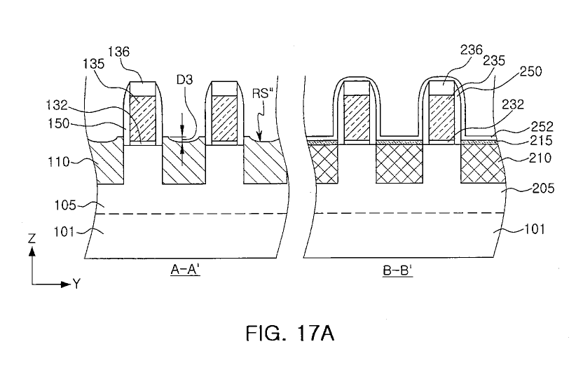

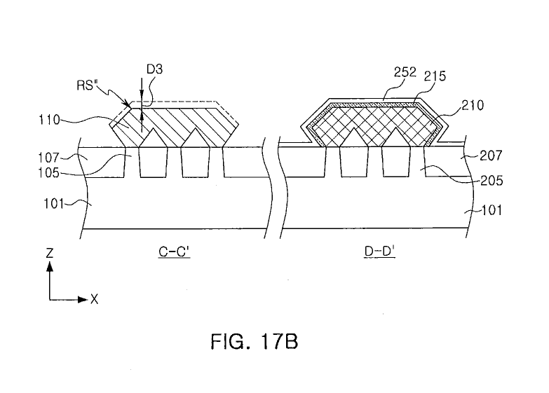

Referring to FIGS. 17A and 17B, recessed portions RS″ spaced apart from the first sidewall spacers 150 at a given distance may be formed by selectively removing the third sidewall spacers 153 and 253 and the sacrificial oxide layers 160 using a wet etching process. The given distance may be determined by thicknesses of the third sidewall spacers 153. The recessed portions RS″ may be formed to have a given depth D3 from upper surfaces of the first embedded sources/drains 110. The recessed portions RS″ may have a shape to which the shape of the upper surfaces of the first embedded sources/drains 110 is transferred.

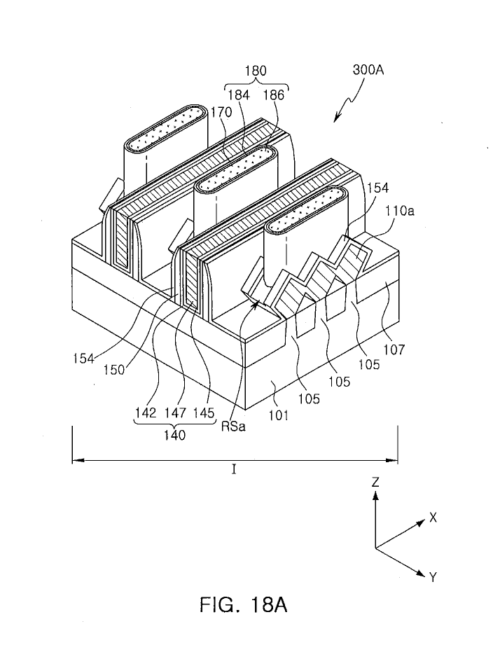

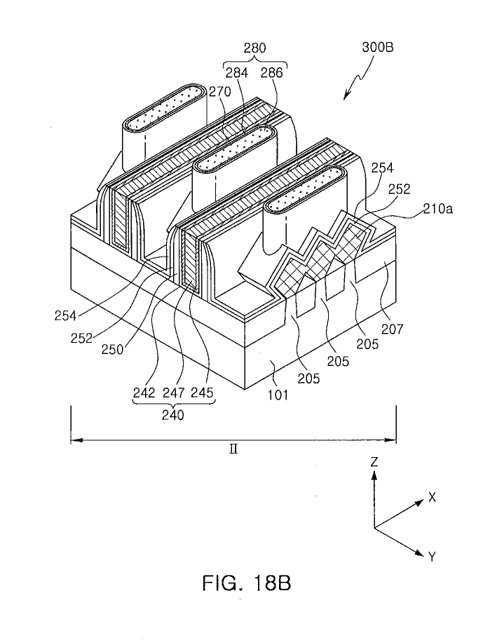

FIGS. 18A and 18B are perspective views illustrating a semiconductor device according to an example embodiment of the present inventive concept.

Referring to FIGS. 18A and 18B, the semiconductor device may include a substrate 101 including a first region I and a second region II, first transistors 300A disposed in the first region I, and second transistors 300B disposed in the second region II.

The first transistors 300A may include first active fins 105, first gate structures 140, first sidewall spacers 150, first embedded sources/drains 110a, and first contact plugs 180, and the second transistor 300B may include second active fins 205, second gate structures 240, second sidewall spacers 250, second embedded sources/drains 210a, and second contact plugs 280. Although structures formed on the substrate 101 are similar to those illustrated in FIGS. 2A and 2B, the shapes of the upper surfaces of the first and second embedded sources/drains 110a and 210a may be different.

In the example embodiment of the present inventive concept, the first embedded sources/drains 110a may have a connected or merged structure on three first active fins 105. Different from those illustrated in FIG. 2A, the merged first embedded sources/drains 110a may have V-shaped upper surfaces between the first active fins 105. The first embedded sources/drains 110a may include recessed portions RSa aligned with the first gate structures 140, and the recessed portions RSa may have a shape to which the shape of the upper surfaces of the first embedded sources/drains 110a is transferred.

Similarly, the second embedded sources/drains 210a may have a connected or merged structure on three second active fins 205. Different from those illustrated in FIG. 2B, the merged second embedded sources/drains 210a may have V-shaped upper surfaces between the second active fins 205.

The number of active fins may not be limited to that illustrated in FIGS. 18A and 18B. For example, the number of the first active fins 105 and the number of the second active fins 205 may be different.

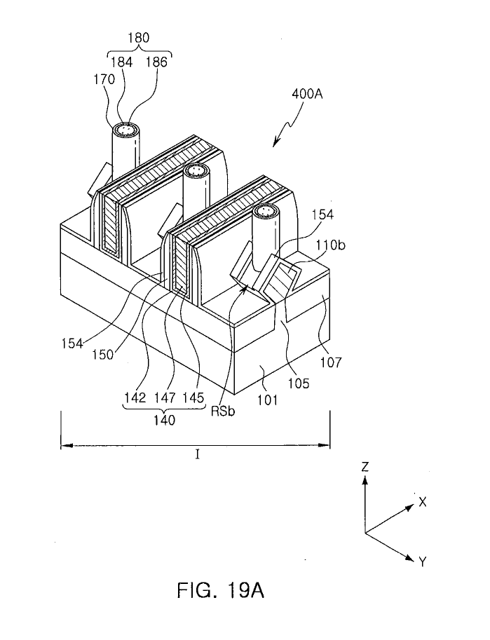

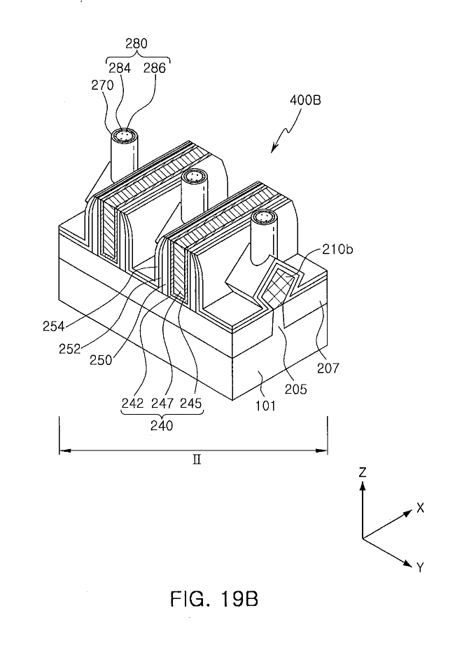

FIGS. 19A and 19B are perspective views illustrating a semiconductor device according to an example embodiment of the present inventive concept.

Referring to FIGS. 19A and 19B, the semiconductor device may include a substrate 101 including a first region I and a second region II, first transistors 400A disposed in the first region I, and second transistors 400B disposed in the second region II.

Although structures formed on the substrate 101 are similar to those illustrated in FIGS. 2A and 2B, the number of active fins forming each transistor may be different.

The first transistors 400A may include one first active fin 105 and first embedded sources/drains 110b disposed on the one first active fin 105, and the second transistor 400B may include one second active fin 205, second gate structures 240, second sidewall spacers 250, second embedded sources/drains 210b, and second contact plugs 280.

The number of active fins may not be limited to that illustrated in FIGS. 19A and 19B. For example, the number of the first active fins 105 and the number of the second active fins 205 may be different.

In the example embodiment of the present inventive concept, the first and second embedded sources/drains 110b and 210b are illustrated as having a pentagonal structure, but are not limited thereto. The first and second embedded sources/drains 110b and 210b may have a variety of shapes.

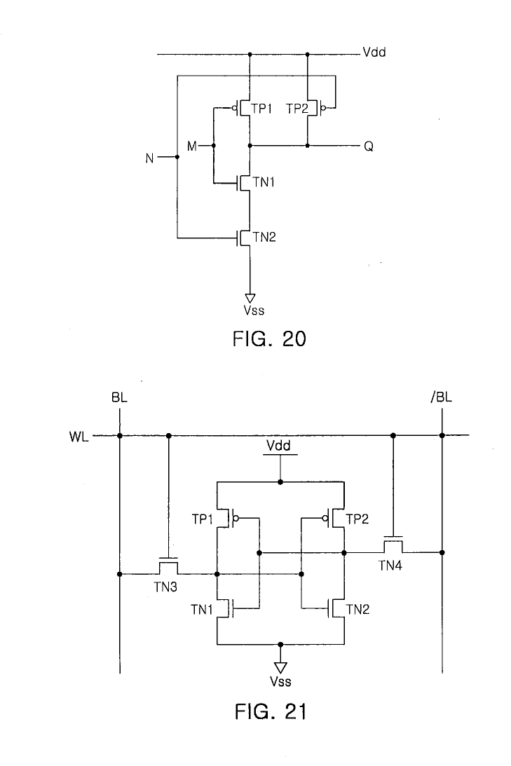

FIG. 20 is a circuit diagram of a NAND gate cell including a semiconductor device to which example embodiments of the present inventive concept can be applied.

Referring to FIG. 20, the NAND gate cell may be configured to receive two input signals M and N and output a signal obtained by performing a NAND operation. The NAND gate cell may include a PMOS field effect transistor (FET) TP1, NMOSFETs TN1 and TN2, and a PMOSFET TP2. The PMOSFETs TP1 may transfer a logical value ‘high’ to an output terminal Q when the input signal M has a logical value ‘low’. When both of the input signals M and N have a logical value ‘high’, the NMOSFETs TN1 and TN2 may be turned on to transfer a logical value ‘low’ to the output terminal Q. The PMOSFET TP2 may transfer a logical value ‘high’ to the output terminal Q when the input signal N has a logical value ‘low’. According to the operation of the NAND gate cell, when both of the input signals M and N have a logical value ‘high’, the PMOSFETs TP1 and TP2 may be turned off and the NMOSFETs TN1 and TN2 may be turned on, to output a logical value ‘low’ to the output terminal Q. In addition, when both of the input signals M and N have a logical value ‘low’, the PMOSFETs TP1 and TP2 may be turned on and the NMOSFETs TN1 and TN2 may be turned off, to output a logical value ‘high’ to the output terminal Q. The transistors may include the semiconductor devices according to the above-described various example embodiments of the present inventive concept.

FIG. 21 is a circuit diagram of an SRAM cell including a semiconductor device to which example embodiments of the present inventive concept can be applied.

Referring to FIG. 21, the SRAM cell may include first and second pull-down transistors TN1 and TN2, first and second pull-up transistors TP1 and TP2, and first and second pass transistors TN3 and TN4. Here, sources of the first and second pull-down transistors TN1 and TN2 may be connected to a ground voltage line Vss, and sources of the first and second pull-up transistors TP1 and TP2 may be connected to a power-supply voltage line Vdd.

In addition, the first pull-down transistor TN1 including an NMOSFET and the first pull-up transistor TP1 including a PMOSFET may be connected in series to configure a first inverter, and the second pull-down transistor TN2 including an NMOSFET and the second pull-up transistor TP2 including a PMOSFET may be connected in series to configure a second inverter. An output terminal of the first inverter may be connected to a source of the first pass transistor TN3, and an output terminal of the second inverter may be connected to a source of the second pass transistor TN4. In addition, input terminals and output terminals of the first and second inverters may be cross-coupled to provide a latch circuit. In addition, drains of the first and second pass transistors TN3 and TN4 may be respectively connected to first and second bit-lines BL and /BL. Gates of the first and second pass transistors TN3 and TN4 may be connected to a word-line WL. The transistors may be formed of the above-described semiconductor devices according to various example embodiments of the present inventive concept.

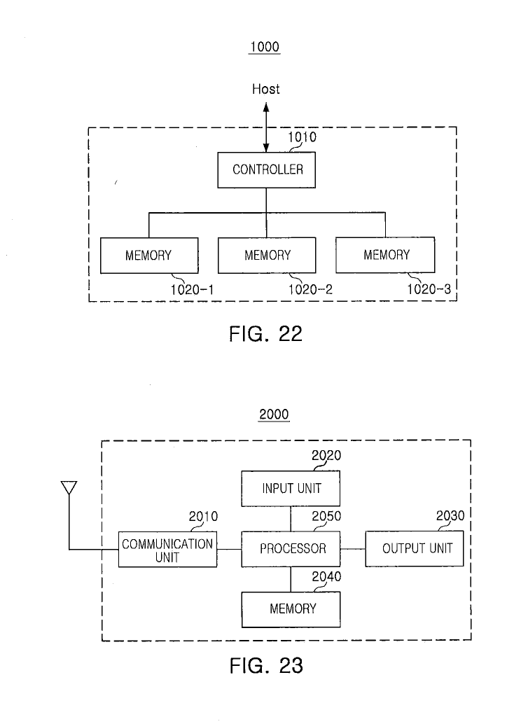

FIG. 22 is a block diagram illustrating a storage apparatus including a semiconductor device to which example embodiments of the present inventive concept can be applied.

Referring to FIG. 22, a storage apparatus 1000 according to an example embodiment of the present inventive concept may include a controller 1010 communicating with a HOST, and memories 1020-1, 1020-2, and 1020-3 storing data. The HOST communicating with the controller 1010 may be a variety of electronic devices in which the storage apparatus 1000 is installed, such as a smartphone, a digital camera, a desktop PC, a laptop computer, or a media player. The controller 1010 may receive a request to read or write data from the HOST to generate a command CMD for writing data to the memories 1020-1, 1020-2, and 1020-3 or reading data from the memories 1020-1, 1020-2, and 1020-3. The controller 1010 or the memories 1020-1, 1020-2, and 1020-3 may include the above-described semiconductor devices according to various example embodiments of the present inventive concept. As illustrated in FIG. 22, one or more memories 1020-1, 1020-2, and 1020-3 may be connected to the controller 1010 in parallel in the storage apparatus 1000. By connecting the plurality of memories 1020-1, 1020-2, and 1020-3 to the controller 1010 in parallel, the storage apparatus 1000 may have large capacity, such as a solid state drive (SSD).

FIG. 23 is a block diagram illustrating an electronic apparatus including a semiconductor device to which example embodiments of the present inventive concept can be applied.

Referring to FIG. 23, an electronic apparatus 2000 according to an example embodiment of the present inventive concept may include a communication unit 2010, an input unit 2020, an output unit 2030, a memory 2040, and a processor 2050.

The communication unit 2010 may include a wired/wireless communications module, such as a wireless internet module, a short-range communications module, a GPS module, or a mobile communications module. The wired/wireless communications module included in the communication unit 2010 may be connected to an external communications network by a variety of communications standards to transmit and receive data. The input unit 2020 is a module supplied for a user to control an operation of the electronic apparatus 2000, and includes a mechanical switch, a touchscreen, a voice recognition module, or the like. In addition, the input unit 2020 may include a trackball, a laser pointer mouse, or a finger mouse, and may further include a variety of sensor modules in which a user can input data. The output unit 2030 may output information processed by the electronic apparatus 2000 in an audio or video form. The memory 2040 may store a program for processing or controlling of the processor 2050, data, or the like. The processor 2050 may write data or read data by transmitting a command to the memory 2040 according to a requested operation. The memory 2040 may be embedded in the electronic apparatus 2000 or communicate with the processor 2050 through a separate interface. When the memory 2040 communicates with the processor 2050 through the separate interface, the processor 2050 may write data to or read data from the memory 2040 by a variety of interface standards, such as SD, SDHC, SDXC, MICRO SD, or USB. The processor 2050 may control operations of each unit included in the electronic apparatus 2000. The processor 2050 may perform controlling or processing operations related to voice calls, video calls, or data communication, or controlling or processing operations for multimedia playback and management. In addition, the processor 2050 may process an input transmitted through the input unit 2020 from a user, and output a result thereof through the output unit 2030. Further, the processor 2050 may write data used to control operations of the electronic apparatus 2000 to the memory 2040, or read the data from the memory 2040, as described above. At least one of the processor 2050 or the memory 2040 may include the above-described semiconductor devices according to various example embodiments of the present inventive concept.

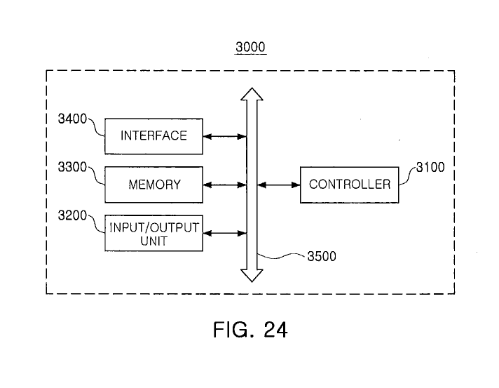

FIG. 24 is a block diagram illustrating a system including a semiconductor device to which example embodiments of the present inventive concept can be applied.

Referring to FIG. 24, a system 3000 may include a controller 3100, an input/output unit 3200, a memory 3300, and an interface 3400. The system 3000 may be a mobile system or an information transmitting or receiving system. The mobile system may be a PDA, a portable computer, a tablet computer, a wireless phone, a mobile phone, a digital music player, or a memory card. The controller 3100 may function to execute a program or control the system 3000. The controller 3100 may be, for example, a microprocessor, a digital signal processor, a microcontroller, or the like. The input/output unit 3200 may be used to input data to the system 3000 or output data from the system 3000. The system 3000 may be connected to an external apparatus, such as a PC or a network, through the input/output unit 3200 to exchange data with the external apparatus. The input/output unit 3200 may be, for example, a keypad, a keyboard, or a display. The memory 3300 may store a code and/or data for operating the controller 3100, and/or data processed in the controller 3100. The interface 3400 may be a data transmission path between the system 3000 and an external apparatus. The controller 3100, the input/output unit 3200, the memory 3300, and the interface 3400 may communicate through a bus 3500. At least one of the controller 3100 and the memory 3300 may include the above-described semiconductor devices according to various example embodiments of the present inventive concept.

As set forth above, according to the example embodiments of the present inventive concept, a method of manufacturing a semiconductor device may be provided. According to the method of the present inventive concept, depths of recessed portions of contact holes can be independently controlled in the N-type transistor and the P-type transistor while simultaneously forming the contact holes. In addition, a semiconductor device having excellent electrical characteristics may be provided.

While example embodiments have been shown and described above, it will be apparent to those skilled in the art that modifications and variations could be made without departing from the scope of the invention as defined by the appended claims.

What is claimed:

1. A semiconductor device comprising:
at least one active fin protruding from a substrate;
a gate structure intersecting the at least one active fin and extending in a first direction;
an embedded source/drain that is on the at least one active fin and comprises an upper surface comprising a recessed portion, wherein the recessed portion extends parallel to the first direction; and
a contact plug partially covering the recessed portion, wherein the recessed portion extends beyond the contact plug in the first direction,
wherein the embedded source/drain comprises opposing ends that are spaced apart from each other in the first direction, and the recessed portion extends from a first one of the opposing ends to a second one of the opposing ends, and
wherein the embedded source/drain further comprises a raised portion that is raised relative to the recessed portion, and the raised portion is between the recessed portion and the gate structure.

2. The semiconductor device of claim 1, further comprising a sidewall spacer disposed on opposing sidewalls of the gate structure,
wherein the recessed portion is spaced apart from the sidewall spacer.

3. The semiconductor device of claim 1, further comprising an etch-stop layer covering the embedded source/drain comprising the recessed portion,
wherein the contact plug extends through the etch-stop layer to be connected to the embedded source/drain.

4. The semiconductor device of claim 3, wherein the etch-stop layer extends on a portion of the recessed portion, and the contact plug does not cover the portion of the recessed portion.

5. The semiconductor device of claim 3, wherein the etch-stop layer is in the recessed portion and extends on opposing sidewalls of the recessed portion.

6. The semiconductor device of claim 3, wherein the recessed portion comprises an exposed portion that is not covered by the contact plug,
wherein the exposed portion of the recessed portion comprises opposing sidewalls and a horizontal surface connected to the opposing sidewalls, and
wherein the etch-stop layer is in the recessed portion and extends on the opposing sidewalls and the horizontal surface of the exposed portion of the recessed portion.

7. The semiconductor device of claim 1, wherein the at least one active fin comprises a plurality of active fins protruding from the substrate, and
wherein the embedded source/drain comprises a merged embedded source/drain structure extending on the plurality of active fins.

8. The semiconductor device of claim 7, wherein the recessed portion of the upper surface of the embedded source/drain comprises a recessed portion of an upper surface of the merged embedded source/drain structure, and
wherein the recessed portion of the upper surface of the merged embedded source/drain structure comprises inclined surfaces at both end portions thereof extending beyond the contact plug and a flat surface between the inclined surfaces.

9. The semiconductor device of claim 1, further comprising:
a silicide layer between the contact plug and the upper surface of the embedded source/drain.

10. The semiconductor device of claim 1, further comprising:
a contact spacer surrounding a side surface of the contact plug.

11. The semiconductor device of claim 1, wherein the at least one active fin comprises silicon comprising P-type impurities.

12. The semiconductor device of claim 1, wherein the embedded source/drain comprises silicon comprising N-type impurities.

13. The semiconductor device of claim 1, wherein the at least one active fin comprises a first active fin of a first conductivity type finFET device, the embedded source/drain comprises a first embedded source/drain on the first active fin, and the raised portion of the embedded source/drain comprises a first raised portion of the first embedded source/drain, and
wherein the semiconductor device further comprises a second conductivity type finFET device comprising a second active fin and a second embedded source/drain on the second active fin, and an upper surface of the second embedded source/drain is at a lower level than an upper surface of the first raised portion of the first embedded source/drain.

14. A semiconductor device comprising:
a first conductivity type finFET device comprising:
a first active fin;
a first gate structure intersecting the first active fin and extending in a first direction;
first embedded sources/drains that comprise a first material having a first etch rate and are on the first active fin; and
first contact plugs partially covering the first embedded sources/drains, respectively,
wherein each of the first embedded sources/drains comprises an upper surface comprising a recessed portion that extends parallel to the first direction and an outer raised portion that is raised relative to the recessed portion and is between the recessed portion and the first gate structure,
wherein each of the recessed portions of the first embedded sources/drains extends beyond a corresponding one of the first contact plugs in the first direction, and
wherein each of the first embedded sources/drains comprises opposing ends that are spaced apart from each other in the first direction, and each of the recessed portions of the first embedded sources/drains extends from a first one of the opposing ends to a second one of the opposing ends; and
a second conductivity type finFET device comprising second embedded sources/drains,
wherein the second embedded sources/drains comprise a second material having a second etch rate that is greater than the first etch rate, and
wherein each of the second embedded sources/drains comprises an upper surface that is at a different level than upper surfaces of the outer raised portions of the first conductivity type finFET device.

15. The semiconductor device of claim 14, wherein each of the recessed portions of the first embedded sources/drains has a depth that is selected to compensate for a difference between the first and second etch rates.

16. The semiconductor device of claim 15, wherein the first material is Si and the second material is SiGe.

17. The semiconductor device of claim 14, further comprising a blocking insulating layer on the second embedded sources/drains,
wherein the blocking insulating layer is absent from being on the first embedded sources/drains.

18. The semiconductor device of claim 14, wherein the first contact plugs are connected to the first embedded sources/drains, respectively,
wherein the semiconductor device further comprises second contact plugs connected to the second embedded sources/drains, respectively, and
wherein bottoms of the first and second contact plugs are coplanar.

19. The semiconductor device of claim 14, wherein each of the recessed portions of the upper surfaces of the first embedded sources/drains comprises inclined surfaces at both end portions thereof extending beyond the corresponding one of the first contact plugs.

20. The semiconductor device of claim 14, further comprising an etch-stop layer covering the first embedded sources/drains comprising the recessed portions, respectively,
wherein the first contact plugs extend through the etch-stop layer to be connected to the first embedded sources/drains, respectively, and
wherein the etch-stop layer is in the recessed portions and extends on opposing sidewalls of each of the recessed portions.
